(19) United States
(12) Patent Application Publication
(10) Pub. No.: US 2006/0103021 A1
(43) Pub. Date: May 18, 2006

(54) BGA package having substrate with exhaust hole

(76) Inventors: Cheng-Cheng Liu, Kaoshiung (TW); Yu-Lung Wen, Kaoshiung (TW); Shi-Yuan Fu, Kaoshiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/272,740

(22) Filed: Nov. 15, 2005

(30) Foreign Application Priority Data
Nov. 15, 2004 (TW) 093134937

(51) Int. Cl. H01L 23/48

(52) U.S. Cl. 257/738

(57) ABSTRACT

The present invention relates to a BGA package having a substrate with an exhaust hole. The BGA package comprises the substrate, a chip and a molding compound. The substrate comprises a plurality of plated through holes electrically connecting an upper surface and a lower surface of the substrate. At least one of the plated through holes located at a predetermined location of the substrate is selected to be formed as an exhaust hole. The exhaust hole passes through the upper surface and the lower surface. When the molding compound is formed to seal the chip, the air inside a mold cavity can be exhausted through the exhaust hole in the selected plated through hole.

### BACKGROUND OF THE INVENTION

1. Field of the Invention

The present invention relates to a BGA package, and particularly to a BGA package having a substrate with an exhaust hole for exhausting air in a mold cavity.

2. Description of the Related Art

In a conventional Ball Grid Array (BGA) package, a chip is disposed on an upper surface of a substrate and sealed by a molding compound. A plurality of external conducting ends (e.g., solder balls) are formed on the lower surface of the substrate and are used for electrically connecting to the outside.

Referring to FIG. 1, in a conventional BGA package 100, a substrate 110 has a plurality of plated through holes 111 that electrically connect an upper surface 112 and a lower surface 113 of the substrate 110. The substrate 110 further comprises a layer of solder mask 114 formed on the upper surface 112 and the lower surface 113 of the substrate 110 respectively to protect a circuit structure (not shown). The solder mask 114 is used for exposing a plurality of conducting fingers 115 on the upper surface 112 and a plurality of solder ball pads 116 on the lower surface 113. Conventionally, the plated through holes 111 are filled with resin 117 therein, and their top and bottom ends are covered by the solder mask 114. A chip 120 is disposed on the upper surface 112 of the substrate 110, and electrically connected to the conducting fingers 115 of the substrate 110 through a plurality of bonding wires 130. Thus, the chip 120 can be electrically connected to the solder ball pads 116 on the lower surface 113 of the substrate 110 through the plated through holes 111. A plurality of external conducting ends 140 (e.g. solder balls) are disposed on the solder ball pads 116 for electrically connecting to the outside.

The conventional BGA package 100 further comprises a molding compound 150 formed on the upper surface 112 of the substrate 110, so as to protect the chip 120 and the bonding wires 130. Before the molding compound 150 is formed, the substrate 110 provided with the chip 120 and the bonding wires 130 is placed in a mold cavity (not shown) of a mold to facilitate the molding of the molding compound 150. Conventionally, the air in the mold cavity is exhausted by the existing exhaust opening of the mold. However, the mold flow of the molding compound 150 on the upper surface 112 of the substrate 110 will be affected due to the design of the chip 120 or other electronic elements on the upper surface 112 of the substrate 110, such that the mold flow speed is not uniform, and the air cannot be exhausted completely from the upper surface 112 of the substrate 110, thus forming plural air bubbles A wrapped between the molding compound 150 and the substrate 110. Moreover, the molding compound 150 will also produce gas during the curing reaction, thus forming plural small air bubbles B around the chip 120. The air bubbles B are too far away from the exhaust opening of the mold to be exhausted.

A substrate disclosed in ROC (Taiwan) publication No. 591768 “Laminated Circuit Substrate and Process thereof” comprises a laminated layer provided with multiple through holes that connect two surfaces of the laminated layer by penetrating the laminated layer. A protective layer for the patterned surface circuit can be filled in the through holes, thus filling up the through holes, besides being formed on the surface of the laminated layer. When the laminated circuit substrate is applied in a chip package, the package molding process cannot be carried out until a chip is adhered on an upper surface of the laminated circuit substrate first. Therefore, an uneven mold flow will occur on the flowing molding compound due to the affect from the chip, thus producing air bubbles in the laminated circuit substrate.

Consequently, there is an existing need for a BGA package having a substrate with an exhaust hole to solve the above-mentioned problems.

### SUMMARY OF THE INVENTION

The object of the present invention is to provide a BGA package having a substrate with an exhaust hole for molding and a substrate thereof, wherein the substrate in the BGA package has an upper surface and a lower surface, and comprises a plurality of plated through holes electrically connecting the upper surface and the lower surface. At least one plated through hole is formed with an exhaust hole passing through the upper surface and the lower surface of the substrate. The exhaust hole is located at a predetermined location of the substrate, which location is the mold flow delay position of the molding compound on the substrate. When the molding compound is formed to seal a chip, the air in a mold cavity is squeezed by the flowing molding compound and exhausted from the exhaust hole, so that a solid molding compound without air bubbles is formed, which is capable of improving the quality of the BGA package.

Another object of the present invention is to provide a BGA package having a substrate with an exhaust hole. A die-attaching area for disposing a chip is defined on an upper surface of a substrate. At least one plated through hole of the substrate is formed with an exhaust hole located outside the die-attaching area, or near an edge or a corner of the substrate. When a molding compound is formed to seal the chip, the air in a cavity of the mold can be exhausted from the exhaust hole to avoid forming the air bubbles.

Still another object of the present invention is to provide a BGA package having a substrate with an exhaust hole. An exhaust hole formed by a plated through hole therein has a cross-section of a V shape or multi-step shape, or the exhaust hole is formed by a combination of multi-layer offset holes communicating with each other to prevent a molding compound from overflowing to the lower surface of the substrate.

According to the present invention, the BGA package having a substrate with an exhaust hole comprises a substrate, a chip and a molding compound. The substrate has an upper surface and a lower surface, and the chip is disposed on the upper surface of the substrate and electrically connected to the substrate. The molding compound is formed on the upper surface of the substrate to seal the chip. The substrate comprises a plurality of plated through holes electrically connecting the upper surface and the lower surface of the substrate, and at least one of the plated through holes at a predetermined location of the substrate is formed with an exhaust hole passing though the upper surface and the lower surface of the substrate for exhausting air when molding.

### BRIEF DESCRIPTION OF THE DRAWINGS

FIG. 1 shows a schematic sectional view of a conventional BGA;

FIG. 2 shows a schematic sectional view of a BGA package having a substrate with an exhaust hole according to a first embodiment of the present invention;

FIG. 3 shows a partial sectional view of the BGA package at an exhaust hole according to the first embodiment of the present invention;

FIG. 4 shows a schematic view of an upper surface of a substrate of the BGA package when forming a molding compound according to the first embodiment of the present invention;

FIG. 5 shows a partial sectional view of a substrate of a BGA package at an exhaust hole according to a second embodiment of the present invention;

FIG. 6 shows a partial sectional view of a substrate of a BGA package at an exhaust hole according to a third embodiment of the present invention; and

FIG. 7 shows a partial sectional view of a substrate of a BGA package at an exhaust hole according to a fourth embodiment of the present invention.

### DETAILED DESCRIPTION OF THE INVENTION

The present invention will be described in the following embodiments with reference to the accompanying drawings.

Referring to FIG. 2, according to a first embodiment of the present invention, a BGA package 200 having a substrate with an exhaust hole comprises a substrate 210, a chip 220, a molding compound 230 and a plurality of external conducting ends 240. The substrate 210 has an upper surface 211 and a lower surface 212. A first solder mask 217 having a plurality of openings 217a is formed on the first surface 211, and a second solder mask 218 having a plurality of openings 218a is formed on the lower surface 212. A plurality of conducting fingers 214 are formed on the upper surface 211 and exposed in the openings 217a, so as to be electrically connected to the chip 220. A plurality of solder ball pads 215 are formed on the lower surface 212 and exposed in the openings 218a, so as to be bonded with the external conducting ends 240. The substrate 210 comprises a plurality of plated through holes 213 and a proper circuit structure (not shown), so as to electrically connect the conducting fingers 214 and the solder ball pads 215. The plated through holes 213 pass through the upper surface 211 and the lower surface 212 of the substrate 210, and can be classified into outer plated through holes and inner plated through holes. In the present embodiment, a die-attaching area 211a (as shown in FIG. 4) is defined on the upper surface 211 of the substrate 210, and is used for disposing the chip 220.

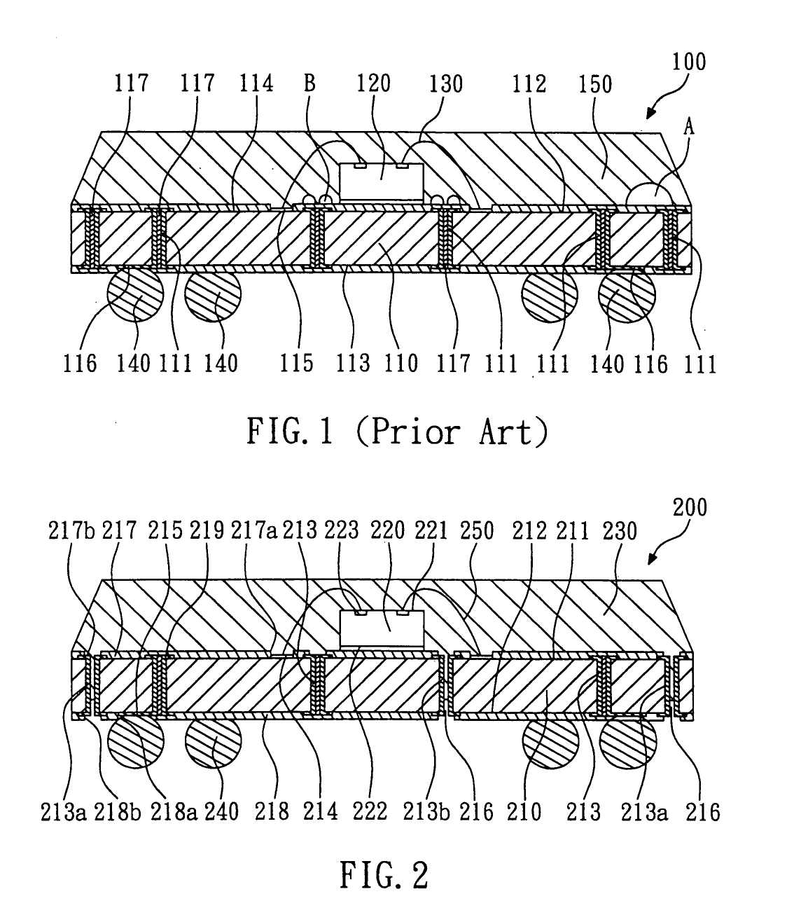

Referring to FIGS. 2, 3 and 4, at least one of the plated through holes 213 is selected as an exhaust plated through hole 213a or 213b, which is located at a predetermined location of the substrate 210, and the predetermined location is the mold flow delay position and inbuilt portion of the molding compound on the substrate. The exhaust plated through holes 213a and 213b are formed with an exhaust hole 216 respectively through the upper surface 211 and the lower surface 212 of the substrate 210 for exhausting air when molding. Generally, the exhaust hole 216 is disposed out of the die-attaching area 211a. In the present embodiment, the exhaust plated through hole 213a is selected from the existing outer plated through holes 213 of the substrate 210. The exhaust plated through hole 213a is not filled with resin and is exposed by the solder masks 217 and 218 on each surface of the substrate 210. The exhaust plated through hole 213a is located near a corner or an edge of the substrate 210 to eliminate the problem of air bubbles A (FIG. 1) in the conventional molding compound. The exhaust plated through hole 213b is selected from the inner plated through holes 213 of the substrate 210. The exhaust plated through hole 213b is not filled with resin and is exposed by the solder masks 217 and 218. The exhaust plated through hole 213b is located near the chip 220 to eliminate the conventional problem of forming air bubbles B (FIG. 1) in the inbuilt portion when curing the molding compound.

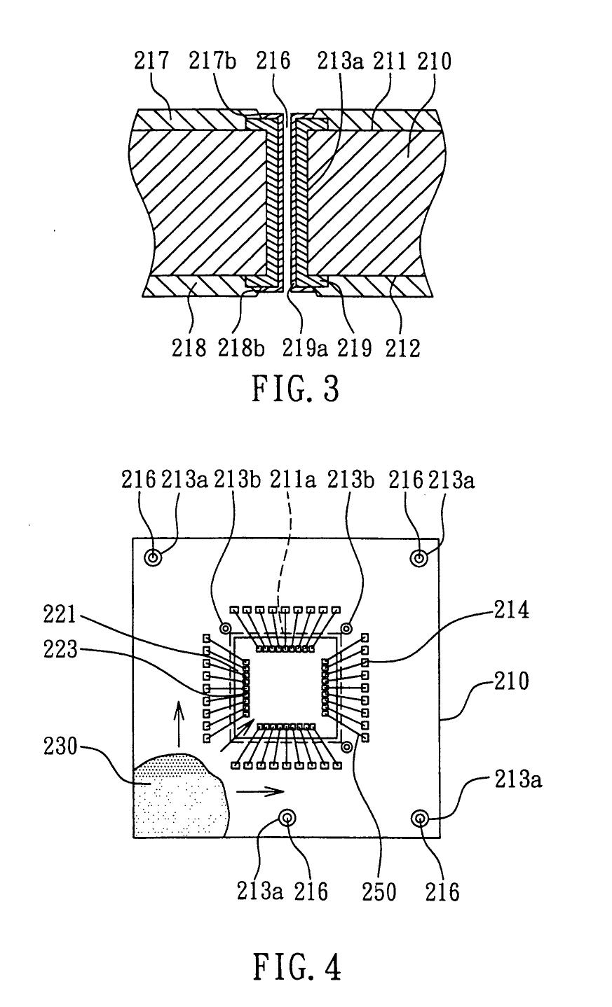

Referring to FIG. 3, the exhaust plated through hole 213a or 213b having exhaust hole 216 is provided with a metal layer 219 on the side wall of the hole for electrically connecting one of the corresponding conducting fingers 214 (FIG. 2) and one of the corresponding solder ball pads 215 (FIG. 2). Preferably, the exhaust plated through hole 213a or 213b having exhaust hole 216 further comprises an oxidation resistance layer 219a (e.g., nickel-gold layer) covered on the metal layer 219. When plating nickel-gold metal layer on the conducting fingers 214 and the solder ball pads 215, the oxidation resistance layer 219a can be formed simultaneously for protecting the metal layer 219. The first solder mask 217 is further formed with at least one opening 217b for exposing one end of the exhaust hole 216, and the second solder mask 218 is further formed with at least one opening 218b for exposing the other end of the exhaust hole 216. Further, the plated through holes 213 that do not serve as exhaust holes are preferably covered by the first solder mask 217 and the second solder mask 218. Therefore, before the substrate 210 is packaged into the semiconductor package, the exhaust hole 216 conducts the upper surface 211 and the lower surface 212, and is not filled with resin, solder mask or other materials, to facilitate the exhaust function for molding, thus eliminating the problem that a molding compound may produce air bubbles at the mold flow delay position and inbuilt portion.

Referring to FIG. 2 again, the chip 220 is disposed on the upper surface 211 of the substrate 210, and has an active surface 221 and a non-active surface 222. A plurality of bonding pads 223 are formed on the active surface 221. In the embodiment, the chip 220 is a wire-bond chip, and the non-active surface 222 of the chip 220 is attached to the die-attaching area 211a (as shown in FIG. 4) with a die-attaching material. The bonding pads 223 of the chip 220 are electrically connected to the conducting fingers 214 of the substrate 210 by a plurality of bonding wires 250. The chip 220 and the bonding wires 250 are sealed by the molding compound 230. The external conducting ends 240 can be disposed on the solder ball pads 215. In the embodiment, the external conducting ends 240 are solder balls and arranged in a matrix to form a BGA package.

Referring to FIGS. 2 and 4, the molding compound 230 is formed by molding. Before the molding compound 230 is formed, the substrate 210 having the chip 220 and the bonding wires 250 is placed in a mold cavity (not shown) of a mold, so as to inject a thermoset material that is used for forming the molding compound 230. Using the exhaust plated through holes 213a and 213b having the exhaust hole 216, in the packing step of forming the molding compound 230, the flowing molding compound 230 still will squeeze the air in the mold cavity and force the air to be exhausted form the exhaust hole 216 of the plated through hole 213a, so as to achieve a solid molding compound 230 without air bubbles. In addition, as shown in FIG. 2, the molding compound 230 can be filled in the exhaust hole 216.

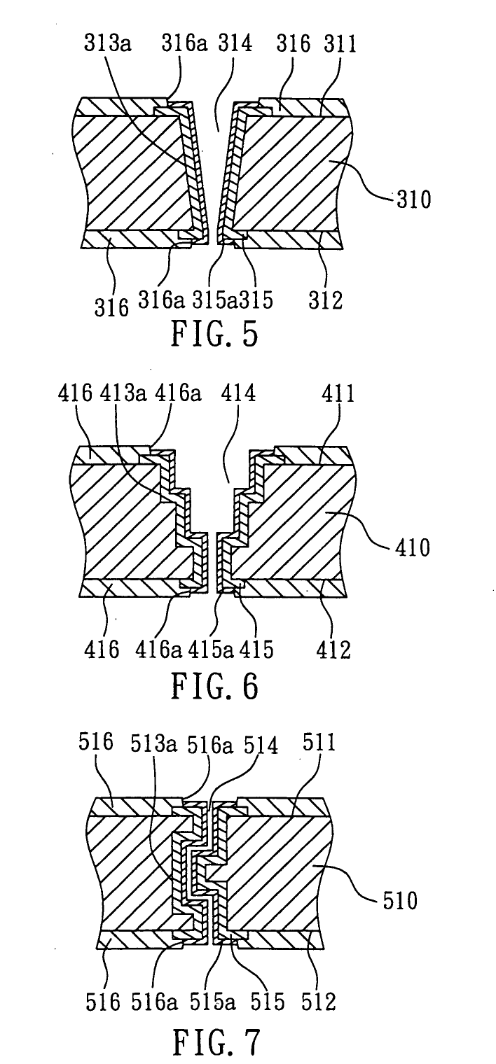

Referring to FIG. 5, according to a second embodiment of the present invention, a substrate 310 applicable to a BGA package has an upper surface 311, a lower surface 312 and a plurality of plated through holes 313a, wherein at least one plated through hole 313a is formed with an exhaust hole 314 passing through the upper surface 311 and the lower surface 312 of the substrate 310, so as to exhaust air when molding. The plated through hole 313a comprises a metal layer 315 and an oxidation resistance layer 315a formed on the inner wall of the plated through hole 313a and extending to the upper surface 311 and lower surface 312. The metal layer 315 is electrically connected between the conducting fingers (not shown) on the upper surface 311 and the solder ball pads (not shown) on the lower surface 312. Moreover, the upper surface 311 and the lower surface 312 of the substrate 310 are formed with a solder mask 316 respectively. The solder mask 316 has an opening 316a for exposing the exhaust hole 314. In the embodiment, the cross-section of the exhaust hole 314 is V-shaped so that the molding compound can be prevented from overflowing to the lower surface 312 of the substrate 310 by reducing the aperture of the exhaust hole 314 gradually.

Referring to FIG. 6, according to a third embodiment of the present invention, a substrate 410 applicable to a BGA package has an upper surface 411, a lower surface 412 and a plurality of plated through holes 431a, wherein at least one plated through hole 413a is formed with an exhaust hole 414. The plated through hole 413a comprises a metal layer 415 on its inner wall and an oxidation resistance layer 415a that covers the metal layer 415. Both ends of the exhaust hole 414 are exposed in the opening 416a of the solder mask 416 respectively, so as to exhaust the air when molding. In the embodiment, the substrate 410 can be a multi-layer printed circuit board, and the cross-section of the exhaust hole 414 can be multi-step shaped so as to prevent a molding compound from overflowing to the lower surface 412 of the substrate 410 by the exhaust hole 414 with multi-layer steps.

Referring to FIG. 7, according to a fourth embodiment of the present invention, a substrate 510 applicable to a BGA package has an upper surface 511, a lower surface 512 and at least one exhaust hole 514 formed in a plated through hole 513a. The plated through hole 513a comprises a metal layer 515, which is formed on the inner wall of the plated through hole 513a and extends from the upper surface 511 to the lower surface 512, and the metal layer 515 is covered by an oxidation resistance layer 515a. Both ends of the exhaust hole 514 are exposed in an opening 516a of a solder mask 516 to pass through the upper surface 511 and the lower surface 512 of the substrate 510, so that the air can be exhausted when forming a molding compound (not shown). In the present embodiment, the substrate 510 can be a laminated multi-layer printed circuit board, and the exhaust hole 514 is formed by a combination of multi-layer offset holes communicating with each other to prevent the molding compound from overflowing to the lower surface 512 of the substrate 510.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A BGA package having a substrate with an exhaust hole, comprising:
a substrate having an upper surface and a lower surface, the substrate comprising a plurality of plated through holes electrically connecting the upper surface and the lower surface, wherein at least one of the plated through holes at a predetermined location of the substrate is formed with an exhaust hole passing through the upper surface and the lower surface of the substrate;
a chip disposed on the upper surface of the substrate and electrically connected to the substrate;
a molding compound formed on the upper surface of the substrate for sealing the chip; and
a plurality of external conducting ends disposed on the lower surface of the substrate.

2. The BGA package according to claim 1, wherein the molding compound is filled in the exhaust hole.

3. The BGA package according to claim 1, wherein a die-attaching area is defined in the upper surface of the substrate, and the exhaust hole is disposed outside the die-attaching area.

4. The BGA package according to claim 3, wherein the substrate comprises a plurality of conducting fingers and a first solder mask on the upper surface, and the first solder mask has a plurality of openings for exposing the conducting fingers and the exhaust hole.

5. The BGA package according to claim 4, wherein the substrate comprises a plurality of solder ball pads and a second solder mask on the lower surface, and the second solder mask has a plurality of openings for exposing the solder ball pads and the exhaust hole.

6. The BGA package according to claim 5, wherein the plated through holes that are not formed with exhaust holes are covered by the first and second solder masks.

7. The BGA package according to claim 5, wherein the plated through holes formed with exhaust holes comprise a metal layer on the hole wall of the plated through holes for electrically connecting one of the conducting fingers and one of the solder ball pads.

8. The BGA package according to claim 5, wherein the plated through holes formed with exhaust holes further comprise an oxidation resistance layer that covers the metal layer.

9. The BGA package according to claim 1, wherein the exhaust hole has an opening in the lower and upper surface, and the opening in the lower surface is smaller than in the upper surface, so as to prevent the molding compound from overflowing to the lower surface of the substrate.

10. The BGA package according to claim 1, wherein the exhaust hole is formed by a combination of multi-layer offset holes so as to prevent the molding compound from overflowing to the lower surface of the substrate.

11. The BGA package according to claim 1, further comprising a plurality of bonding wires for electrically connecting the chip and the substrate.

12. A substrate having an exhaust hole, wherein the substrate has an upper surface and a lower surface, and the substrate comprises a plurality of plated through holes electrically connecting the upper surface and the lower surface of the substrate, and at least one of the plated through holes at a predetermined location of the substrate is formed with an exhaust hole passing through the upper surface and the lower surface of the substrate.

13. The substrate according to claim 12, wherein a die-attaching area is defined in the upper surface of the substrate, and the exhaust hole is disposed outside the die-attaching area.

14. The substrate according to claim 12, further comprising a plurality of conducting fingers and a first solder mask formed on the upper surface, wherein the first solder mask has a plurality of openings for exposing the conducting fingers and the exhaust hole.

15. The substrate according to claim 14, further comprising a plurality of solder ball pads and a second solder mask formed on the lower surface, wherein the second solder mask has a plurality of openings for exposing the solder ball pads and the exhaust hole.

16. The substrate according to claim 15, wherein the plated through holes that are not formed with exhaust holes are covered by the first and second solder masks.

17. The substrate according to claim 15, wherein the plated through holes formed with exhaust holes comprise a metal layer on the hole wall for electrically connecting one of the conducting fingers and one of the solder ball pads.

18. The substrate according to claim 17, wherein the plated through holes formed with exhaust holes further comprise an oxidation resistance layer that covers the metal layer.

19. The substrate according to claim 12, wherein the exhaust hole has an opening in the lower and upper surface, and the opening in the lower surface is smaller than in the upper surface, so as to prevent the molding compound from overflowing to the lower surface of the substrate.

20. The substrate according to claim 12, wherein the exhaust hole is formed by a combination of multi-layer offset holes for preventing the molding compound from overflowing to the lower surface of the substrate.
